(19) United States
(12) Patent Application Publication
(10) Pub. No.: US 2026/0047149 A1
(43) Pub. Date: Feb. 12, 2026

(54) MESA JFET WITH CHANNEL ENGINEERING

(71) Applicant: Microchip Technology Incorporated, Chandler, AZ (US)

(72) Inventors: Shesh Mani Pandey, Gilbert, AZ (US); Randy L. Yach, Phoenix, AZ (US)

(73) Assignee: Microchip Technology Incorporated, Chandler, AZ (US)

(21) Appl. No.: 19/285,538

(22) Filed: Jul. 30, 2025

Related U.S. Application Data
(60) Provisional application No. 63/682,255, filed on Aug. 12, 2024.
(60) Provisional application No. 63/704,408, filed on Oct. 7, 2024.

(51) Int. Cl. H10D 30/83; H10D 30/01; H10D 62/17

(52) U.S. Cl. CPC H10D 30/831; H10D 30/0515; H10D 62/328

(57) ABSTRACT

A mesa junction field-effect transistor is provided with channel engineering, and a method of making such a device is disclosed. A volume of semiconductor material includes a first end, a second end, a first side, and a second side. A channel extends between a source located at the first end and a drain. A first gate is located at the first side. A second gate is located at the second side, opposite the first gate, and includes upper and lower components located along an opposite side of the channel. The lower second gate component is spaced below and extends beneath the source, thereby creating at least two turns in the channel. The first and second gates cooperate to provide multiple control points in the non-linear channel for controlling electrical current flowing through the channel.

### RELATED APPLICATION

The present U.S. non-provisional patent application is related to and claims priority benefit of earlier-filed U.S. provisional patent application titled “Mesa JFET with Channel Engineering,” Ser. No. 63/704,408, filed Oct. 7, 2024; and earlier-filed U.S. provisional patent application titled “Planar JFET with Shielded Source,” Ser. No. 63/682,255, filed Aug. 12, 2024. The entire content of the identified earlier-filed application is incorporated by reference as if fully set forth herein.

### FIELD

The present disclosure relates to field-effect transistors and methods of making them, and, more particularly, the various examples described herein concern a mesa field-effect transistor with channel engineering, and a method of making a mesa field-effect transistor with channel engineering.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide a mesa field-effect transistor with channel engineering, and a method of making a mesa field-effect transistor with channel engineering. Broadly, a gate component partially extends into a semiconductor channel region of the field-effect transistor beneath a source, thereby shielding the source, creating turns in the channel, and providing at least one control point for controlling current flow through the non-linear channel. Examples advantageously provide improved performance, including reduced drain induced barrier loading (DIBL) which avoids the device inadvertently turning on, and improved current control.

In an example, a FET with channel engineering may include a source, a drain, a channel, a first gate, and a second gate. The drain may be located spaced apart from the source, and the channel may extend between the source and the drain. The first gate may be located along a first side of the channel. The upper surface of the first gate may be lower than an upper surface of the source. The second gate may be located along a second side of the channel opposite the first gate and include a lower second gate component spaced below and extending beneath the source and creating at least two turns in the channel, and an upper second gate component located above the lower second gate component. An upper surface of the second gate component may be lower than the upper surface of the source. The channel is non-linear between the source and the drain due to the lower second gate component. A first leg of the channel may extend vertically from the source, and the first gate and the upper second gate component may cooperate to create a first control point in the first leg of the channel to control an electrical current flowing through the channel. A second leg of the channel may extend laterally beneath the source and the drain. A third leg of the channel may extend to the drain.

The preceding example may include one or more of the following features. The upper surfaces of the first and second gates may be coplanar. Each of the first and second gates may present a lower surface opposite from the upper surface thereof, and the lower surfaces of the first and second gates may be coplanar. The drain may be spaced vertically opposite from the source, such that the lower second gate component is vertically positioned at least in part between the source and the drain to thereby shield the source. The third leg of the channel may extend vertically to the drain. The upper surfaces of the first and second gates may be spaced apart a lateral dimension, the lower second gate component may extend the lateral dimension so as to extend continuously beneath the source, and the first gate and the lower second gate component may cooperate to create a second control point in the second leg of the channel. The first gate may present a lower surface opposite from the upper surface thereof, and the lower second gate component may be vertically lower than the lower surface of the first gate. The first gate may include a lower first gate component spaced laterally from the lower second gate component, wherein the lower first gate component and the lower second gate component cooperate to create a third control point in the third leg of the channel. The first gate may include an upper first gate component, and the lower first gate component may have a lateral dimension less than the upper first gate component, such that the upper first gate component overhangs the third leg of the channel. A volume of semiconductor material may be provided, wherein the volume of semiconductor material may have vertically spaced first and second ends and laterally spaced first and second sides. The source may be located at the first end of the volume of semiconductor material, the first gate may be located along the first side of the volume of semiconductor material, and the second gate may be located along the second side of the volume of semiconductor material. The source may include an N-type material, the drain may include an N-type material, and the first and second gates may include a P-type material. The first gate may include a lower first gate component spaced laterally from the lower second gate component, and the lower first gate component and the lower second gate component may cooperate to create a third control point in the third leg of the channel.

In another example, a method of making a JFET with channel engineering may include the following operations. A substrate material may be provided. A volume of semiconductor material may be grown on the substrate material, the volume of semiconductor material may include vertically spaced first and second ends and laterally spaced first and second sides. A drain may be provided. A source may be provided at the first end of the volume of semiconductor material. A first gate component may be provided at the first side of the volume of semiconductor material, and a lower second gate component may be provided at the second side of the volume of semiconductor material and extending into the volume of semiconductor material toward the first side so as to at least in part be spaced apart from and extend beneath the source. An upper second gate component maybe provided above the lower second gate component. The volume of semiconductor material may be etched along the first side thereof so that an upper surface of the first gate component is lower than an upper surface of the source, and the volume of semiconductor material may be etched along the second side thereof so that an upper surface of the second gate component is lower than the upper surface of the source. The lower second gate component may create a non-linear channel between the source and the drain. A first leg of the channel may extend vertically from the source, and the first gate and the upper second gate component may cooperate to create a first control point in the first leg of the channel to control an electrical current flowing through the channel. A second leg of the channel may extend laterally beneath the source. A third leg of the channel may extend to the drain.

The preceding example may further include one or more of the following features. The steps of etching along the first and second sides of the volume of semiconductor material may be performed so that the upper surface of the first gate and the upper surface of the upper second gate component are coplanar. The step of etching along the first side of the volume of semiconductor material may include etching a first trench through a first side of the source and into the first gate, and the step of etching along the second side of the volume of semiconductor material may include etching a second trench through a second side of the source and into the upper second gate component, such that a center portion of the source remains and is higher than the upper surface of the first gate component and the upper second gate component. The steps of providing the first gate component and the lower second gate component may be performed such that the first gate component and the lower second gate component cooperate to create a second control point in the second leg of the channel. A lower first gate component may be provided, with the lower first gate component cooperating with and the lower second gate component cooperate to create a third control point in the third leg of the channel. The steps of providing the first gate component, the upper second gate component, and the lower second gate component may include implanting such components within the volume of semiconductor material. The steps of providing the first gate and the upper second gate component may include spacing the upper surfaces thereof a lateral dimension, and the step of providing the lower second gate component may include extending the lower second gate component the lateral dimension such that the lower second gate component extends continuously beneath the source.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of a first example of a mesa JFET with channel engineering;

FIG. 2 is a flowchart of operations in a first example of a method of making a mesa JFET with channel engineering, such as the mesa JFET of FIG. 1;

FIG. 3A is a cross-sectional elevation view of the result of an operation in the method of FIG. 2, wherein an N-type epitaxial semiconductor material is provided on an N+ substrate, and first and second P+ gate structures and an N+ source are implanted in the semiconductor material;

FIG. 3B is a cross-sectional elevation view of the result of an operation in the method of FIG. 2, wherein third and fourth P+ gate structures are implanted;

FIG. 3C is a cross-sectional elevation view of the result of an operation in the method of FIG. 2, wherein first and second trenches are etched;

FIG. 3D is a cross-sectional elevation view of the result of an operation in the method of FIG. 2, wherein fifth and sixth P+ gate structures are implanted;

FIG. 3E is a cross-sectional elevation view of the result of an operation in the method of FIG. 2, wherein electrical terminals are provided;

FIG. 4 is a cross-sectional elevation view of a second example of a mesa JFET with channel engineering;

FIG. 5 is a flowchart of operations in a second example of a method of making a mesa JFET with channel engineering, such as the mesa JFET of FIG. 5;

FIG. 6A is a cross-sectional elevation view of the result of an operation in the method of FIG. 5, wherein an N-epitaxial semiconductor material is provided on an N+ substrate, and a first, second, and third P+ gate structures and an N+ source are implanted in the semiconductor material;

FIG. 6B is a cross-sectional elevation view of the result of an operation in the method of FIG. 5, wherein first and second trenches are etched;

FIG. 6C is a cross-sectional elevation view of the result of an operation in the method of FIG. 5, wherein a fourth P+ gate structure is implanted; and

FIG. 6D is a cross-sectional elevation view of the result of an operation in the method of FIG. 5, wherein electrical terminals are provided.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Examples provide a mesa JFET with channel engineering, and a method of making a mesa JFET with channel engineering. Broadly, a gate component partially extends into a semiconductor channel region of the JFET beneath a source, thereby shielding the source, creating turns in the channel, and providing at least one control point for controlling current flow through the non-linear channel. Examples advantageously provide improved performance, including reduced DIBL which avoids the device inadvertently turning on, and improved current control.

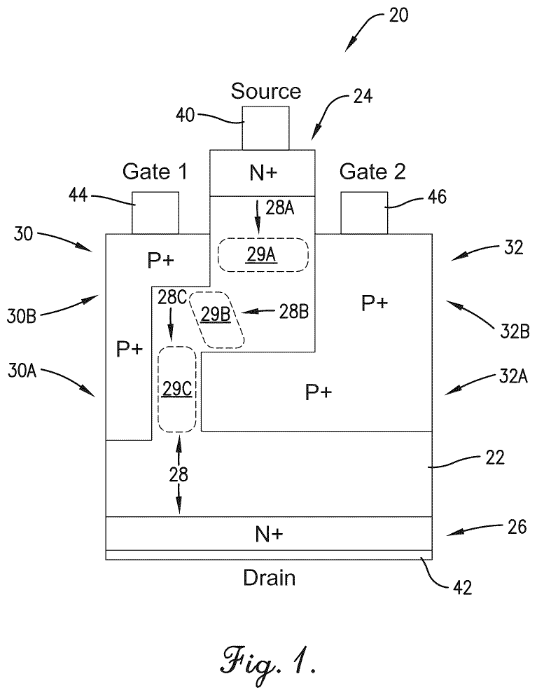

Referring to FIG. 1, a first example of a mesa JFET 20 with a shielded source and multiple control points for controlling current may include a volume of semiconductor material 22, a source 24, a drain 26, a channel 28, a first gate 30, and a second gate 32. The volume of semiconductor material 22 may include a first end, a second end, a first side, and a second side. The semiconductor material 22 may be constructed from or include an N-type epitaxial semiconductor material. The source 24 may be located at or near the first end of the semiconductor material 22 and provide an entrance for the majority charge carriers (e.g., electrons for N-channel) into the channel 28. As seen in FIG. 1, the source 24 may be positioned higher than the adjacent first and second gates 30, 32, which is the “mesa” configuration. The source 24 may be constructed from or include an N+ material.

The drain 26 may be located at or near the second end of the semiconductor material 22, spaced apart from and opposite the source 24, and provide an exit for the majority charge carriers from the channel 28. However, in certain aspects, the drain may alternatively be located within the volume of semiconductor material (e.g., on the same end as the source). The drain 24 may be constructed from or include an N+ substrate material. The channel 28 may be provided by a region of the semiconductor material 22 between the source 24 and the drain 26 and through which the majority charge carriers move, i.e., through which electric current flows. It will be appreciated that the majority charge carriers, which are, in this present example, electrons, flow from the source 24 to the drain 26, and the conventional current, Id, flows from the drain 26 to the source 24.

The first gate 30 may be generally located along the first side of the semiconductor material 22, and along a first side of the channel 28 which extends through the semiconductor material 22, generally opposite the second gate 32, and spaced apart from and lower than the source 24. The first gate 30 may include a lower first gate component 30A and an upper first gate component 30B. The lower first gate component 30A may be generally located below the upper first gate component 30B. The lower and upper first gate components 30A, 30B may both be constructed from or include a P+ material.

The second gate 32 may include a lower second gate component 32A generally located along the second side of the semiconductor material 22, and along a second side of the channel 28, generally opposite the lower first gate component 30A, spaced apart from and lower than the source 24, and partially extending beneath the source 24. In this example, the lower second gate component 32A is positioned between the source 24 and the drain 26. The lower second gate component 32A may provide a “shield” for the source 24 and create at least two turns in the channel 28. The second gate 32 may also include an upper second gate component 32B generally located above the lower second gate component 32A and generally opposite the upper first gate component 30B. The lower and upper second gate components 32A, 32B may both be constructed from or include a P+ material. The upper limits of the upper components 30B, 32B of the first and second gates 30, 32 may be coplanar or approximately coplanar, and the lower limits of the lower components 30A, 32A of the first and second gates 30, 32 may be coplanar or approximately coplanar. The upper limits (or surfaces) of the upper gate components 30B and 32B may be spaced apart a lateral dimension. The lower second gate component 32A may extend continuously the full lateral dimension so as to extend continuously beneath the full lateral width of the source. Further, because of the degree to which the lower second gate component 32A extends laterally and the lateral dimension of the upper first gate component 30B, the lower first gate component 30A is laterally thinner than the upper first gate component 30B. The upper first gate component 30B thereby overhangs a portion of the channel (the third leg as described below). In alternative examples, the lower second gate component 32A may extend less than the lateral dimension defined between the upper surfaces of the upper gate components 30B, 32B or extend beyond the lateral dimension to partially underlie a portion of the upper first gate component 30B.

As seen in FIG. 1, the channel 28 is non-linear between the source 24 and the drain 26 due to the lower second gate component 32B extending beneath the source 24, such that a first leg 28A of the channel 28 extends vertically from the source 24. In the present example, such vertical extension of the first leg 28A is toward (i.e. in the direction of) the drain 26. The upper first gate component 30B and the upper second gate component 32B may cooperate to create a first control point 29A for controlling an electrical current flowing through the channel 28. The channel 28 turns and a second leg 28B of the channel 28 extends generally laterally (or parallel to the source 24 and the drain 26). The extension of the lower second gate component 32A relative to the upper first gate component 30B is such that the lower second gate component 32A and the upper first gate component 30B cooperate to create a second control point 29B. The channel 28 turns again, and a third leg 28C of the channel 28 extends to the drain 26. Because of the extension and lateral location of the lower first gate component 30A relative to the lower second gate component 32A, the lower first and second gate components 30A, 32A cooperate to create a third control point 29C. Thus, the first and second gates 30, 32 cooperate to create multiple control points 29A, 29B, 29C for controlling current flow through the non-linear channel 28.

The source 24 may include a first electrical terminal 40, the drain 26 may include a second electrical terminal 42, the first gate 30 may include a third electrical terminal 44, and the second gate 32 may include a fourth electrical terminal 46 for facilitating connections to appropriate voltage sources, as described below.

In operation, an input voltage, Vds, may be applied across the first and second electrical terminals 40, 42 to cause electron drift/movement from the source 24 to the drain 26, and a control voltage, Vgs, may be applied across the first and third electrical terminals 40, 44 to control the width of the depletion region at the P-N junctions where the charge carriers of the P- and N-type materials diffuse into each other, which “depletes” the available concentrations of majority charge carriers in each material, and thereby control the current, Id, from the drain 26 to source 24. Thus, the source 24, the first gate 30, and the second gate 32 may cooperate under Vgs to control the current, Id, through the channel 28. If Vgs=0 V and Vds>0 V, electrons drift, or move, from the source to the drain, resulting in a current, Id, from the drain 26 to the source 24, and increased depletion regions at the P-N junctions. If Vds=pinch-off voltage (Vp), then the depletion regions increase in size and grow sufficiently close to each other across the channel 28 that the current, Id, through the channel cannot increase and so is at its maximum, Id=(max drain current (Idss)). In the present examples, the shielding of the source 24 by the lower second gate component 32A reduces a reverse bias leakage current and provides a higher breakdown voltage (BVgs) for the JFET 20, and the first and second gates 30, 32 cooperate to create multiple control points 29A, 29B, 29C for controlling current flow through the channel 28.

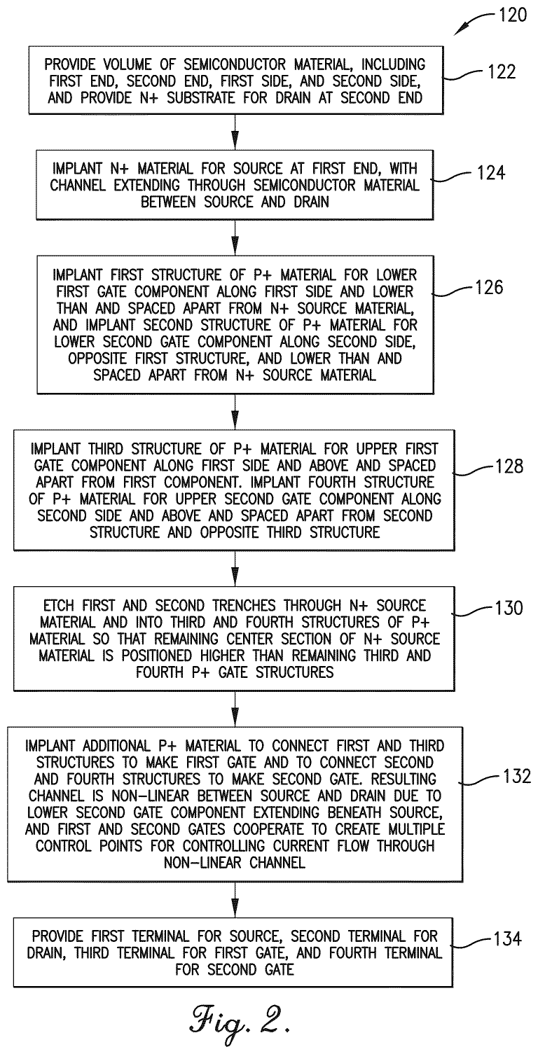

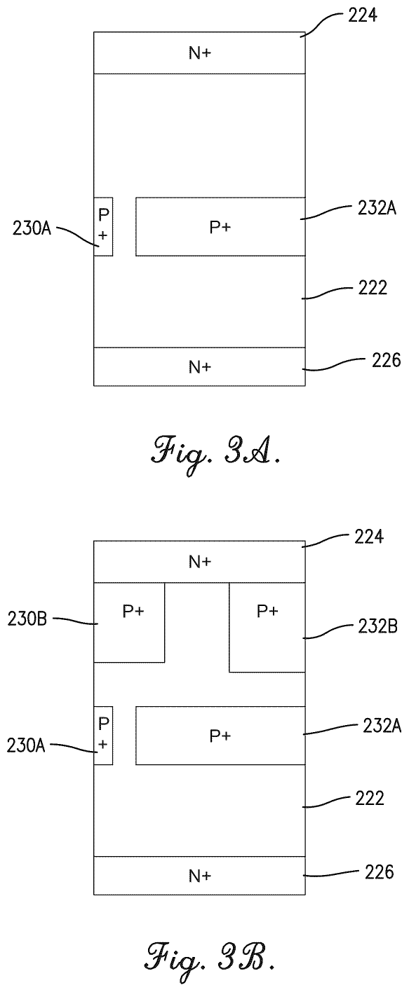

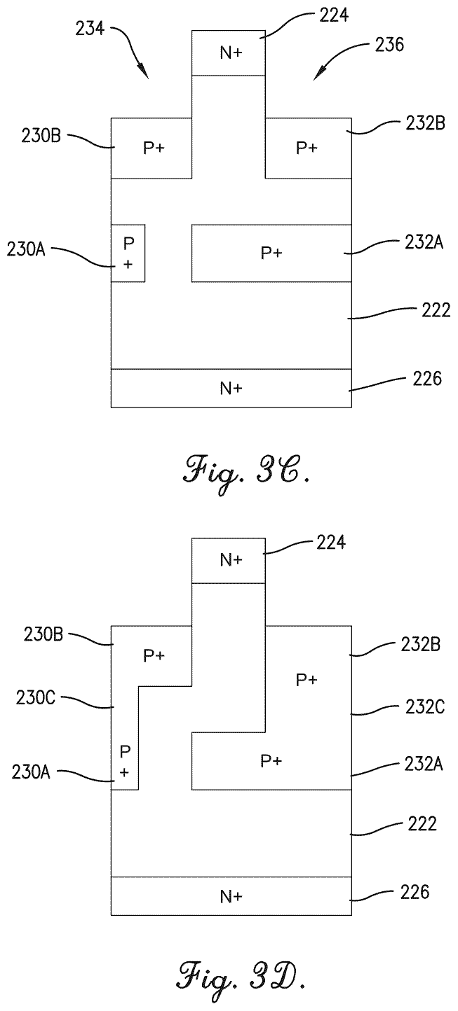

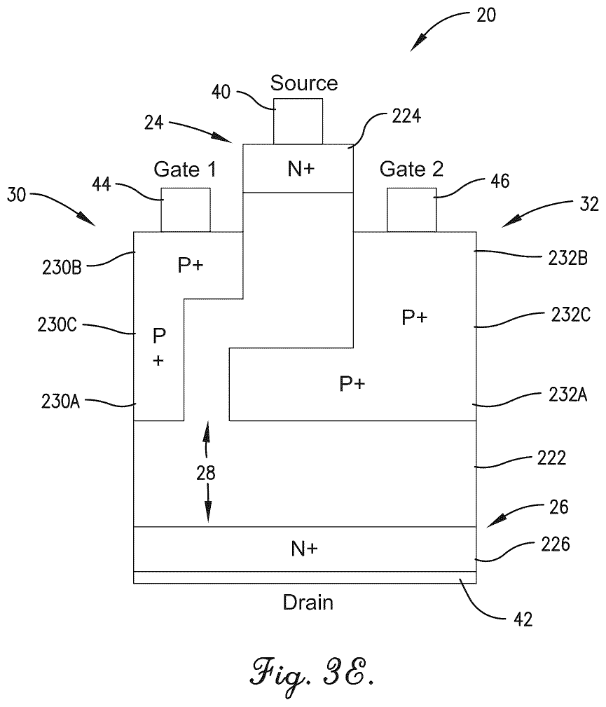

Referring to FIG. 2, a first example of a method 120 of making a mesa JFET with channel engineering, such as the mesa JFET 20 described above, may include the operations set forth below. Referring additionally to FIGS. 3A-E, example results are shown of the operations of the method 120, which may be stages in the manufacture of the mesa JFET 20.

An N+ substrate 226, which may become the drain 26, may be provided, and a volume of semiconductor material 222 may be grown or otherwise provided on the substrate 220, as shown in 122 and seen in FIG. 3A. The N+ substrate 226 may be constructed from or include a 4H-SiC material, and the semiconductor material 222 may be constructed from or include an N+ epitaxial semiconductor material. The volume of semiconductor material 222 may include a first end, a second end, a first side, and a second side, and the N+ substrate 226 may be located at the second end. A structure of N+ source material 224, which may become the source 24, may be implanted or otherwise provided at or near the first end of the semiconductor material 22, as shown in 124 and also seen in FIG. 3A.

First and second structures of P+ material 230A, 232A, which may become the lower components 30A, 32A of the first and second gates 30, 32, may be implanted in the volume of semiconductor material 222, as shown in 126 and also seen in FIG. 3A. The first structure of P+ material 230A may be implanted along the first side of the semiconductor material 22 and lower than and spaced apart from the implanted N+ source material 224. The second structure of P+ material 232A may be implanted along the second side of the semiconductor material 222, generally opposite the first structure 230A, and lower than and spaced apart from the implanted N+ source material 224. As seen in FIG. 3A, the first structure 230A may be relative smaller than the second structure 232A, with the second structure 232A extending farther into the semiconductor material 222 toward the first structure 230A, such that a gap between the first and second structures 230A, 232A, which will become a leg of the channel 28, is offset toward the first side of the volume of semiconductor material 222. The lower limits of the first and second structures of P+ materials 230A, 232A may be coplanar or approximately coplanar. The second structure of P+ material 232A, which may become the lower second gate component 32A, may provide the “shield” for the source 24 in the finished JFET 20.

Third and fourth structures of P+ material 230B, 232B, which may become the upper components 30B, 32B of the first and second gates 30, 32, may be implanted in the volume of semiconductor material 222 generally above the first and second components 230A, 232A, respectively, as shown in 128 and seen in FIG. 3B. The third structure of P+ material 230B may be implanted along the first side of the semiconductor material 222 and above than the first structure 230A. The third structure 230B may be spaced apart from the first structure 230A such that a gap of semiconductor material exists between them. The fourth structure of P+ material 232B may be implanted along the second side of the semiconductor material 222 and above the second structure 232A and generally opposite the third structure 230B. The fourth structure 232B may be spaced apart from the second structure 232A such that a gap of semiconductor material exists between them. As seen in FIG. 3B, the third and fourth structures 230B, 232B may be the same or substantially the same size and spaced apart such that a gap between the first and second structures 230B, 232B, which will become a leg of the channel 28, is centered between the first and second sides of the volume of semiconductor material 222. The upper and lower limits of the third and fourth structures of P+ materials 230B, 232B may be coplanar or approximately coplanar.

First and second trenches 234, 236 may be etched through the N+ source material 224 and into the third and fourth structures of P+ material 230B, 232B so that the remaining center section of the N+ source material 224 is positioned higher than the remaining third and fourth P+ gate structures 230B, 232B, which is the “mesa” configuration, as shown in 130 and seen in FIG. 3C. Additional P+ material 230C, 232C may be implanted to fill the gap between the first and third structures 230A, 230B, thereby connecting them together to form the first gate 30, and to fill the gap between the second and fourth structures 232A, 232B, thereby connecting them together to form the second gate 32, as shown in 132 and seen in FIG. 3D.

Referring again to FIG. 1, the resulting channel 28 is non-linear between the source 24 and the drain 26 due to the lower second gate component 32B extending beneath the source 24, such that a first leg 28A of the channel 28 extends from the source 24 toward the drain 26, and the upper first gate component 30B and the upper second gate component 32B cooperate to create first control point 29A for controlling an electrical current flowing through the channel 28; the channel 28 turns and a second leg 28B of the channel 28 extends parallel to the source 24 and the drain 26 and the upper first gate component 30B and the lower second gate component 32A cooperate to create a second control point 29B; and the channel 28 turns again, and a third leg 28C of the channel 28 extends to the drain 26 and the lower first gate component 30A and the lower second gate component 32A cooperate to create a third control point 29C. Thus, the first and second gates 30, 32 cooperate to create multiple control points 29A, 29B, 29C for controlling current flow through the non-linear channel 28.

A first electrical terminal 40 may be provided for the source 24, a second electrical terminal 42 may be provided for the drain 26, a third electrical terminal 44 may be provided for the first gate 30, and a fourth electrical terminal 46 may be provided for the second gate 32 for facilitating connections to appropriate voltage sources, as described above, as shown in 134 and seen in FIG. 3E. Additional processing may be performed as desired.

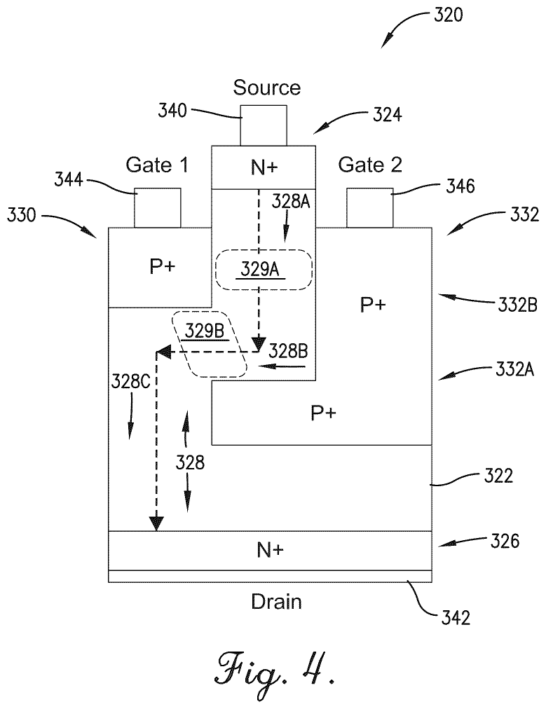

Referring to FIG. 4, a second example of a mesa JFET 320 with a shielded source and multiple control points may include a volume of semiconductor material 322, a source 324, a drain 326, a channel 328, a first gate 330, and a second gate 332. Alternatives described above with respect to the first example mesa JFET 20 equally apply to the second example mesa JFET 320, unless expressly described to the contrary or as might be appreciated by one of ordinary skill in the art.

The volume of semiconductor material 322 may include vertically spaced first and second ends and laterally spaced first and second sides. The semiconductor material 322 may be constructed from or include an N-type epitaxial semiconductor material. The source 324 may be located at or near a first end of the semiconductor material 322 and provide an entrance for the majority charge carriers (e.g., electrons for N-channel) into the channel 328. As seen in FIG. 4, the source 324 may be positioned higher than the adjacent to the first and second gates 330, 332, which is the “mesa” configuration. The source 324 may be constructed from or include an N+ material.

The drain 326 may be located at or near a second end of the semiconductor material 322, spaced apart from and opposite the source 324, and provide an exit for the majority charge carriers from the channel 328. The drain 326 may be constructed from or include an N+ substrate material. The channel 328 may be provided by a region of the semiconductor material 322 between the source 324 and the drain 326 and through which the majority charge carriers move, i.e., through which electric current flows. It will be appreciated that the majority charge carriers, which are, in this present example, electrons, flow from the source 324 to the drain 326, and the conventional current, Id, flows from the drain 326 to the source 324.

The first gate 330 may be generally located along a first side of the semiconductor material 322, and along a first side of the channel 328 which extends through the semiconductor material 322, and spaced apart from and lower than the source 324. The first gate 330 may be constructed from or include a P+ material.

The second gate 332 may include a lower second gate component 332A generally located at and along a second side of the semiconductor material 322, and along a second side of the channel 328, spaced apart from and lower than the first gate 330 and the source 324, and partially extending beneath the source 324. The lower second gate component 332A may provide a “shield” for the source 324. The second gate 332 may also include an upper second gate component 332B generally located above the lower second gate component 332A and generally opposite the first gate 330. The lower and upper second gate components 332A, 332B may both be constructed from or include a P+ material.

In this example, the first gate component 330 may have a lower limit (or surface) that is spaced above the lower limit (or surface) of the lower second gate component 332A. Further, the lower second gate component 332A may be spaced entirely below the lower limit of the first gate component 330. Yet further, the lower second gate component 332A may extend the full lateral dimension defined between the upper limits (or surfaces) of the first gate component 330 and upper second gate component 332B. In other examples, the lower second gate component 332A may extend beyond the lateral dimension and thereby underlie a portion of the first gate component 330.

As seen in FIG. 4, the channel 328 is non-linear between the source 324 and the drain 326 due to the lower second gate component 332B extending beneath the source 324, such that a first leg 328A of the channel 328 extends from the source 324 toward (i.e., in the direction of) the drain 326, and the first gate component 330 and the upper second gate component 332B cooperate to create first control point 329A for controlling an electrical current flowing through the channel 328. The channel 328 turns and a second leg 328B of the channel 328 extends generally laterally (parallel to the source 324 and the drain 326). Because of the relative spacing of the first gate component 330 and the lower second gate component 332A, and the first gate component 330 and the lower second gate component 332A cooperate to create a second control point 329B. The channel 328 turns again, and a third leg 328C of the channel 328 extends to the drain 326. Thus, the first and second gates 330, 332 cooperate to create multiple control points 329A, 329B for controlling current flow through the non-linear channel 328.

The source 324 may include a first electrical terminal 340, the drain 326 may include a second electrical terminal 342, the first gate 330 may include a third electrical terminal 344, and the second gate 332 may include a fourth electrical terminal 346 for facilitating connections to appropriate voltage sources, as described below.

In operation, an input voltage, Vds, may be applied across the first and second electrical terminals 340, 342 to cause electron drift/movement from the source 324 to the drain 326, and a control voltage, Vgs, may be applied across the first and third electrical terminals 340, 344 to control the width of the depletion region at the P-N junctions where the charge carriers of the P- and N-type materials diffuse into each other, which “depletes” the available concentrations of majority charge carriers in each material, and thereby control the current, Id, from the drain 326 to source 324. Thus, the source 324, the first gate 330, and the second gate 332 may cooperate under Vgs to control the current, Id, through the channel 328. If Vgs=0 V and Vds>0 V, electrons drift, or move, from the source 324 to the drain 326, resulting in a current, Id, from the drain 326 to the source 324, and increased depletion regions at the P-N junctions. If Vds=pinch-off voltage (Vp), then the depletion regions increase in size and grow sufficiently close to each other across the channel 328 that the current, Id, through the channel 328 cannot increase and so is at its maximum, Id=(max drain current (Idss)). In the present examples, the shielding of the source 324 by the lower second gate component 332A reduces a reverse bias leakage current and provides a higher breakdown voltage (BVgs) for the JFET 320, and the first and second gates 330, 332 cooperate to create multiple control points for controlling current flow through the channel 328.

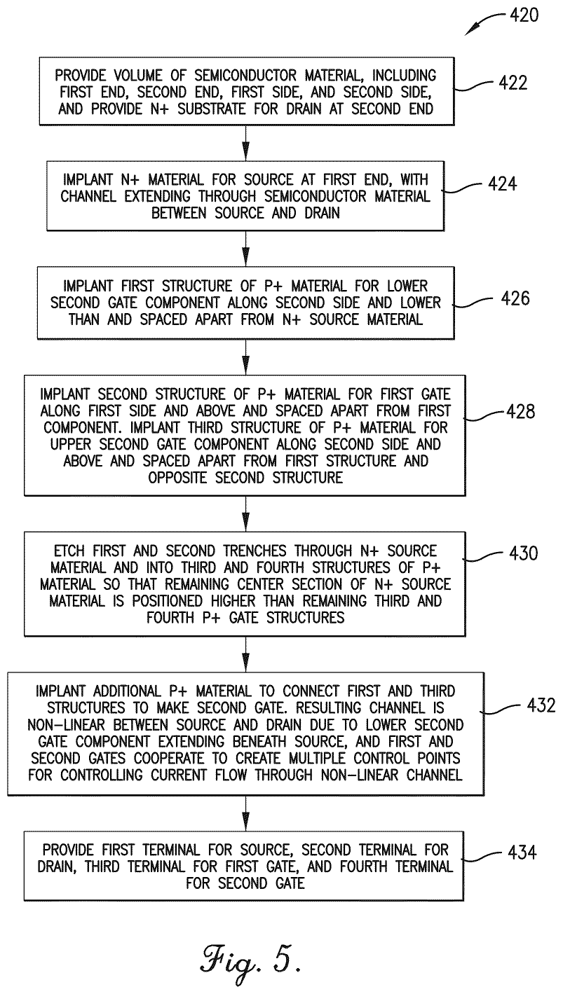

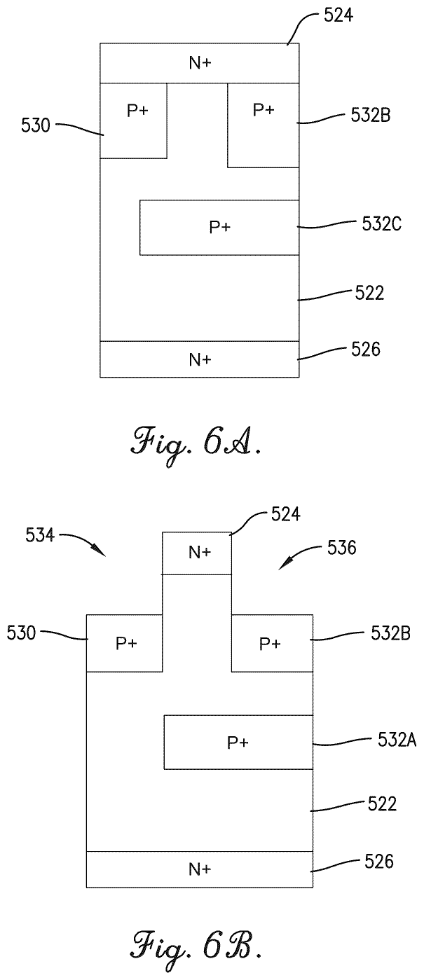

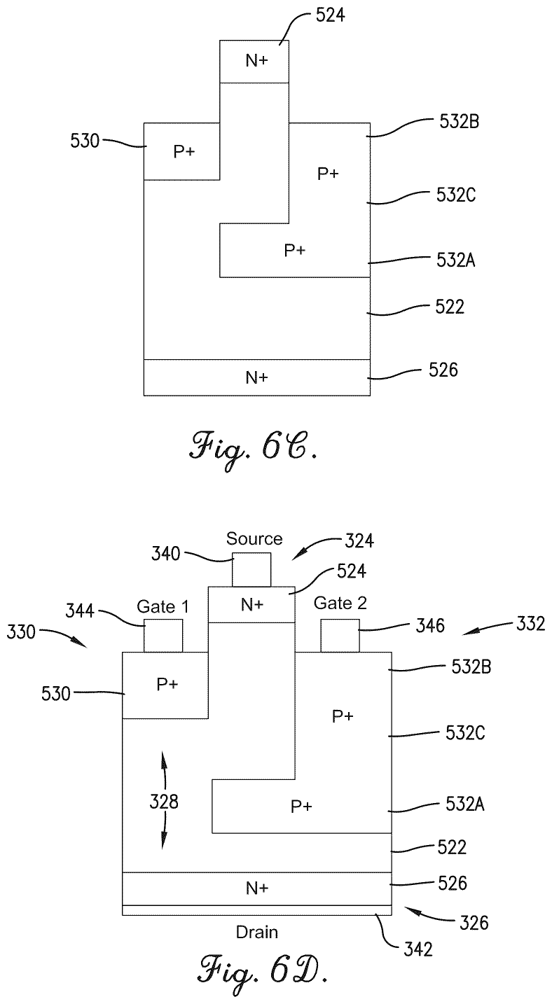

Referring to FIG. 5, a second example of a method 420 of making a mesa JFET with channel engineering, such as the second example mesa JFET 320 of FIG. 4, described above, may include the operations set forth below. Referring additionally to FIGS. 6A-D, example results are shown of the operations of the method 420, which may be stages in the manufacture of the JFET 320.

An N+ substrate material 526, which may become a drain 326, may be provided, and a volume of semiconductor material 522 may be grown or otherwise provided on the substrate 526, as shown in 422 and seen in FIG. 6A. The N+ substrate material 526 may be constructed from or include a 4H-SiC material, and the semiconductor material 522 may be constructed from or include an N+ epitaxial semiconductor material. The volume of semiconductor material 522 may include a first end, a second end, a first side, and a second side, and the N+ substrate material 526 may be located at the second end. A structure of N+ material 524, which may become the source 324, may be implanted or otherwise provided at the first end of the semiconductor material 522, as shown in 424 and also seen in FIG. 6A.

A first structure of P+ material 532A, which may become the lower component 332A of the second gate 332, may be implanted in the volume of semiconductor material 522, as shown in 426 and also seen in FIG. 6A. The first structure of P+ material 532A may be implanted along the second side of the semiconductor material 522, lower than and spaced apart from the implanted N+ source material 524, and extend below the N+ source material 524, such that the region of semiconductor material that will become a leg of the channel 328 is offset toward the first side of the volume of semiconductor material 522. The first structure of P+ material 532A, which may become the lower second gate component 332A, may provide the “shield” for the source 324 in the finished JFET 320.

Second and third structures of P+ material 530, 532B, which may become the first gate 330 and the upper component 332B of the second gate 332, may be implanted in the volume of semiconductor material 522 below the N+ source material 524, with the third structure of P+ material 532B being generally located above the first structure of P+ material 532A, as shown in 428 and seen in FIG. 6A. The second structure of P+ material 530 may be implanted along the first side of the semiconductor material 522. The third structure of P+ material 532B may be implanted along the second side of the semiconductor material 522 and higher than the first structure 532A and generally opposite the second structure 530. The third structure 532B may be spaced apart from the first structure 532A such that a gap of semiconductor material exists between them. As seen in FIG. 6A, the second and third structures 530, 532B may be the same or substantially the same size and spaced apart such that a gap between the second and third structures 530, 532B, which will become a leg of the channel 328, is centered between the first and second sides of the volume of semiconductor material 324. The upper limits of the second and third structures of P+ materials 530, 532B may be coplanar or approximately coplanar, and the lower limits of the second and third structures of P+ materials 530, 532B may be coplanar or approximately coplanar.

First and second trenches 534, 536 may be etched through the N+ source material 524 and into the second and third structures of P+ material 530, 532B so that the remaining center section of the N+ source material 524 is positioned higher than the remaining second and third P+ gate structures 530, 532B, which is the “mesa” configuration, as shown in 430 and seen in FIG. 6B. Additional P+ material 532C may be implanted to fill the gap between the first and third structures 532A, 532B, thereby connecting them together to form the second gate 332, as shown in 432 and seen in FIG. 6C.

Referring again to FIG. 4, the resulting channel 328 is non-linear between the source 324 and the drain 326 due to the lower second gate component 332B extending beneath the source 324, such that a first leg 328A of the channel 328 extends from the source 324 toward the drain 326, and the upper first gate component 330B and the upper second gate component 332B cooperate to create first control point 329A for controlling an electrical current flowing through the channel 328; the channel 328 turns and a second leg 328B of the channel 328 extends parallel to the source 324 and the drain 326 and the upper first gate component 330B and the lower second gate component 332A cooperate to create a second control point 329B; and the channel 328 turns again, and a third leg 328C of the channel 328 extends to the drain 326. Thus, the first and second gates 330, 332 cooperate to create multiple control points 329A, 329B for controlling current flow through the non-linear channel 328.

A first electrical terminal 340 may be provided for the source 324, a second electrical terminal 342 may be provided for the drain 326, a third electrical terminal 344 may be provided for the first gate 330, and a fourth electrical terminal 346 may be provided for the second gate 332 for facilitating connections to appropriate voltage sources as shown in 434 and seen in FIG. 6D. Additional processing may be performed as desired.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide (Al2O3), hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10\hat{ }18 and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

It will be appreciated that the sides of the illustrated volume of semiconductor material are defined herein merely as an example, and may in various examples represent only a portion of semiconductor material relative to the illustrated device. In practice, the volume of semiconductor may extend laterally (leftward and rightward when viewing FIG. 1 or 4) beyond the bounds illustrated in the drawings to present additional semiconductor material in which additional devices may be provided. (The semiconductor material may similarly extend inwardly or outwardly (relative to the lateral or cross-sectional direction depicted in FIG. 1 or 4) to present additional devices in a direction transverse to the lateral direction.) Such additional devices may be FETs (which may be similarly or alternatively constructed to the illustrated device 20 or 320) or may be entirely different devices providing different operations or functions than the illustrated devices. In other words, in practice, each of the illustrated devices may be just one of numerous devices spaced laterally and transversely within a single, integrally formed component, such as a wafer (not shown).

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A field-effect transistor with channel engineering, the field-effect transistor comprising:
a source;
a drain located spaced apart from the source;
a channel extending between the source and the drain;
a first gate located along a first side of the channel, wherein an upper surface of the first gate is lower than an upper surface of the source; and
a second gate located along a second side of the channel opposite the first gate and including—
a lower second gate component spaced below and extending beneath the source and creating at least two turns in the channel, and
an upper second gate component located above the lower second gate component, wherein an upper surface of the second gate component is lower than the upper surface of the source,
wherein the channel is non-linear between the source and the drain due to the lower second gate component, such that—
a first leg of the channel extends vertically from the source, and the first gate and the upper second gate component cooperate to create a first control point in the first leg of the channel to control an electrical current flowing through the channel,
a second leg of the channel extends laterally beneath the source, and
a third leg of the channel extends to the drain.

2. The field-effect transistor of claim 1,
the upper surfaces of the first and second gates being coplanar.

3. The field-effect transistor of claim 2,
each of the first and second gates presenting a lower surface opposite from the upper surface thereof,
the lower surfaces of the first and second gates being coplanar.

4. The field-effect transistor of claim 1,
the drain being spaced vertically opposite from the source, such that the lower second gate component is vertically positioned at least in part between the source and the drain to thereby shield the source,
the third leg of the channel extends vertically to the drain.

5. The field-effect transistor of claim 4,
the upper surfaces of the first and second gates being spaced apart a lateral dimension,
the lower second gate component extending the lateral dimension so as to extend continuously beneath the source,
the first gate and the lower second gate component cooperating to create a second control point in the second leg of the channel.

6. The field-effect transistor of claim 5,
the first gate presenting a lower surface opposite from the upper surface thereof,
the lower second gate component being vertically lower than the lower surface of the first gate.

7. The field-effect transistor of claim 5,
the first gate including a lower first gate component spaced laterally from the lower second gate component, wherein the lower first gate component and the lower second gate component cooperate to create a third control point in the third leg of the channel.

8. The field-effect transistor of claim 7,
the first gate including an upper first gate component,
the lower first gate component having a lateral dimension less than the upper first gate component, such that the upper first gate component overhangs the third leg of the channel.

9. The field-effect transistor of claim 1,
the upper surfaces of the first and second gates being spaced apart a lateral dimension,
the lower second gate component extending the lateral dimension so as to extend continuously beneath the source,
the first gate and the lower second gate component cooperating to create a second control point in the second leg of the channel.

10. The field-effect transistor of claim 1,
the first gate including a lower first gate component spaced laterally from the lower second gate component, wherein the lower first gate component and the lower second gate component cooperate to create a third control point in the third leg of the channel.

11. The field-effect transistor of claim 10,
the upper surfaces of the first and second gates being spaced apart a lateral dimension,
the lower second gate component extending the lateral dimension so as to extend continuously beneath the source,
the first gate and the lower second gate component cooperating to create a second control point in the second leg of the channel.

12. The field-effect transistor of claim 11,
the first gate including an upper first gate component,
the lower first gate component having a lateral dimension less than the upper first gate component, such that the upper first gate component overhangs the third leg of the channel.

13. The field-effect transistor of claim 1, comprising:
a volume of semiconductor material having vertically spaced first and second ends and laterally spaced first and second sides,
the source being located at the first end of the volume of semiconductor material,
the first gate being located along the first side of the volume of semiconductor material,
the second gate being located along the second side of the volume of semiconductor material.

14. The field-effect transistor of claim 13,
the source including an N-type material,
the drain including an N-type material,
the first gate including a P-type material,
the second gate including a P-type material.

15. A method of making a junction field-effect transistor with channel engineering, the method comprising:
providing a substrate material;
growing a volume of semiconductor material on the substrate material, the volume of semiconductor material including vertically spaced first and second ends and laterally spaced first and second sides;
providing a drain;
providing a source at the first end of the volume of semiconductor material;
providing a first gate component at the first side of the volume of semiconductor material;
providing a lower second gate component at the second side of the volume of semiconductor material and extending into the volume of semiconductor material toward the first side so as to at least in part be spaced from and extend beneath the source;
providing an upper second gate component above the lower second gate component;
etching the volume of semiconductor material along the first side thereof so that an upper surface of the first gate component is lower than an upper surface of the source;
etching the volume of semiconductor material along the second side thereof so that an upper surface of the upper second gate component is lower than the upper surface of the source,
wherein the lower second gate component causes the channel extending between the source and the drain to be non-linear, with—
a first leg of the channel extending vertically from the source, and the first gate and the upper second gate component cooperate to create a first control point in the first leg of the channel to control an electrical current flowing through the channel,
a second leg of the channel extends laterally beneath the source, and
a third leg of the channel extends to the drain.

16. The method of claim 15,
the steps of etching along the first and second sides of the volume of semiconductor material being performed so that the upper surface of the first gate and the upper surface of the upper second gate component are coplanar.

17. The method of claim 15,
the step of etching along the first side of the volume of semiconductor material including etching a first trench through a first side of the source and into the first gate,
the step of etching along the second side of the volume of semiconductor material including etching a second trench through a second side of the source and into the upper second gate component, such that a center portion of the source remains and is higher than the upper surface of the first gate component and the upper second gate component.

18. The method of claim 15,
the steps of providing the first gate component and the lower second gate component being performed such that the first gate component and the lower second gate component cooperate to create a second control point in the second leg of the channel; and
providing a lower first gate component that cooperates with the lower second gate component to create a third control point in the third leg of the channel.

19. The method of claim 15,
the steps of providing the first gate component, the upper second gate component, and the lower second gate component including implanting such components within the volume of semiconductor material.

20. The method of claim 15,
the steps of providing the first gate and the upper second gate component including spacing the upper surfaces thereof a lateral dimension,
the step of providing the lower second gate component including extending the lower second gate component the lateral dimension such that the lower second gate component extends continuously beneath the source.
